(19) United States
(12) Patent Application Publication
(10) Pub. No.: US 2024/0378347 A1
(43) Pub. Date: Nov. 14, 2024

(54) GENERATING DIGITAL TWINS OF SEMICONDUCTOR MANUFACTURING EQUIPMENT

(71) Applicant: Lam Research Corporation, Fremont, CA (US)

(72) Inventors: Sassan Roham, San Ramon, CA (US); Michal Danek, Cupertino, CA (US); Kapil Sawlani, Ann Arbor, MI (US)

(21) Appl. No.: 18/259,953

(22) PCT Filed: Jan. 10, 2022
(86) PCT No.: PCT/US2022/070118

§ 371 Date: Jun. 29, 2023

Related U.S. Application Data
(60) Provisional application No. 63/199,667, filed on Jan. 15, 2021.

(51) Int. Cl. G06F 30/27; G06F 30/17

(52) U.S. Cl. CPC G06F 30/27; G06F 30/17

(57) ABSTRACT

Various embodiments herein relate to systems, methods, and media for generating digital twins of semiconductor manufacturing equipment. In some embodiments, a digital twin of a process chamber of semiconductor manufacturing equipment is provided. comprising one or more non-transitory machine readable media comprising logic configured to implement; a first model of a first location of the process chamber; and a second model of a second location of the process chamber, wherein the first model is coupled to the second model, and wherein the first model and the second model are each of a model type that is one of: 1) an AI/ML model; 2) an HFS model; and 3) a closed-form solution, and wherein the first model and the second model each represent a class of physical phenomena that is one of: 1) thermal characteristics; 2) plasma characteristics; 3) fluid dynamics; 4) structural characteristics; and 5) chemical reactions.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

It may be useful to provide a model of an entire process chamber used to fabricate electronic devices such as semiconductor integrated circuits. For example, such a model may be used to evaluate a fabrication recipe, a design of components of the process chamber, etc. However, it can be difficult to provide a model of the entire process chamber, because a typical process chamber involves many different physical phenomena (e.g., fluid dynamics, temperature and temperature flux, plasma behavior, chemical reactions, structural characteristics, etc.) that interact in complex ways. Moreover, models of different components of a reactor or process chamber may require very different timescales or spatial scales for accuracy, therefore making it difficult to combine models of different components.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor implicitly admitted as prior art against the present disclosure.

### SUMMARY

Disclosed herein are methods, systems, and media for generating digital twins of semiconductor manufacturing equipment.

In accordance with some embodiments of the disclosed subject matter, a digital twin of a process chamber of semiconductor manufacturing equipment, comprising one or more non-transitory machine readable media is provided, where the machine readable media comprises logic configured to implement: a first model of a first location of the process chamber; and a second model of a second location of the process chamber, wherein the first model of the first location of the process chamber is coupled to the second model of the second location of the process chamber, and wherein the first model of the first location of the process chamber and the second model of the second location of the process chamber are each of a model type that is one of: 1) an AI/ML model; 2) an HFS model; and 3) a closed-form solution, and wherein the first model of the first location of the process chamber and the second model of the second location of the process chamber each represent a class of physical phenomena that is one of: 1) thermal characteristics; 2) plasma characteristics; 3) fluid dynamics; 4) structural characteristics; and 5) chemical reactions.

In some embodiments, the first model of the first location of the process chamber is of a different model type than the second model of the second location of the process chamber.

In some embodiments, the first model of the first location of the process chamber represents a different class of physical phenomena than the second model of the second location of the process chamber.

In some embodiments, the first location is one of: 1) a pedestal of an ESC; 2) a showerhead; 3) a gap between the pedestal and the showerhead; 4) a chamber wall; and 5) a surface of a wafer fabricated by the process chamber.

In some embodiments, the first model of the first location of the process chamber being coupled to the second model of the second location of the process chamber comprises the first model of the first location of the process chamber providing outputs to the second model of the second location of the process chamber for use by the second model of the second location of the process chamber.

In some embodiments, the first model of the first location of the process chamber being coupled to the second model of the second location of the process chamber comprises the first model of the first location of the process chamber receiving outputs from the second model of the second location of the process chamber for use by the first model of the first location of the process chamber.

In accordance with some embodiments of the disclosed subject matter, a computer program product for generating digital twins of process chambers is provided, the computer program product comprising a non-transitory computer readable medium on which is provided computer-executable instructions for: generating a digital twin by; generating, for a first location of a process chamber, a plurality of High Fidelity Simulation (HFS) values using an HFS model of the first location of the process chamber; receiving a plurality of sensor measurements corresponding to the first location of the process chamber; training an Artificial Intelligence/Machine Learning (AI/ML) model of the first location of the process chamber using at least one of the plurality of HFS values and the plurality of sensor measurements; and coupling the trained AI/ML model of the first location of the process chamber to a model of a second location of the process chamber, wherein the digital twin of the process chamber is comprised of the trained AI/ML model of the first location of the process chamber and the model of the second location of the process chamber.

In some embodiments, the second model of the second location of the process chamber is one of: 1) an AI/ML model; 2) an HFS model; and 3) a closed-form solution.

In some embodiments, the HFS model of the first location of the process chamber and the AI/ML model of the first location of the process chamber both model a same class of physical phenomena.

In some embodiments, the trained AI/ML model of the first location of the process chamber and the model of the second location of the process chamber each model a class of physical phenomena.

In some embodiments, the class of physical phenomena is one of: thermal characteristics, plasma characteristics, fluid dynamics, structural characteristics, and chemical reactions.

In some embodiments, the trained AI/ML model of the first location of the process chamber and the model of the second location of the process chamber model different classes of physical phenomena.

In some embodiments, the HFS model of the first location of the process chamber generates simulation values with a timestep that is shorter than a timestep of the AI/ML model of the first location of the process chamber.

In some embodiments, the first location of the process chamber is one of: 1) a pedestal of an electrostatic chuck (ESC); 2) a showerhead; 3) a gap between the showerhead and the pedestal; 4) a chamber wall; and 5) a surface of a wafer fabricated by the process chamber.

In some embodiments, coupling the trained AI/ML model of the first location of the process chamber to the model of the second location of the process chamber comprises providing a plurality of outputs of the trained AI/ML model of the first location of the process chamber to the model of the second location of the process chamber.

In some embodiments, providing the plurality of outputs of the trained AI/ML model of the first location of the process chamber to the model of the second location of the process chamber comprises: waiting until the plurality of outputs of the trained AI/ML model of the first location of the process chamber have been received; and transmitting the plurality of outputs to the model of the second location of the process chamber.

In some embodiments, coupling the trained AI/ML model of the first location of the process chamber to the model of the second location of the process chamber comprises providing a plurality of outputs of the model of the second location of the process chamber to the trained AI/ML model of the first location of the process chamber.

In some embodiments, the computer program product further comprises computer-executable instructions for validating a performance of the trained AI/ML model of the first location of the process chamber after inclusion of the trained AI/ML model of the first location of the process chamber in the digital twin.

In some embodiments, validating the performance of the trained AI/ML model comprises: generating simulated data using the digital twin that includes the trained AI/ML model of the first location of the process chamber and the model of the second location of the process chamber; and comparing the simulated data to experimental data collected using a plurality of sensors associated with a physical process chamber.

In some embodiments, the model of the second location of the process chamber is an HFS model, and further comprising computer-executable instructions for replacing the HFS model of the second location of the process chamber with a trained AI/ML model of the second location in the digital twin.

In accordance with some embodiments of the disclosed subject matter, a computer program product for using digital twins of process chambers is provided, the computer program product comprising a non-transitory computer readable medium on which is provided computer-executable instructions for: identifying a plurality of inputs to a digital twin of a process chamber, wherein the digital twin comprises a first model of a first location of the process chamber and a second model of a second location of the process chamber, and wherein the first model of the first location of the process chamber and the second model of the second location of the process chamber are coupled, and wherein the plurality of inputs represent operating conditions of the process chamber; providing the plurality of inputs to the digital twin; and generating predicted wafer characteristics of a simulated wafer using the digital twin.

In some embodiments, the first model of the first location of the process chamber includes specifications of a component of the process chamber, and further comprising computer-executable instructions for validating the specifications of the component based on the predicted wafer characteristics.

In some embodiments, the plurality of inputs include parameters of a recipe implemented by the process chamber, and further comprising computer-executable instructions for validating at least one parameter of the recipe based on the predicted wafer characteristics.

In some embodiments, the predicted wafer characteristics comprise an indication of a defect of the simulated wafer.

In some embodiments, the computer program product further comprises computer-executable instructions for identifying a recommendation to modify at least one operating condition of the operating conditions based on the predicted wafer characteristics.

In some embodiments, wherein the recommendation is identified in response to determining that the predicted wafer characteristics indicate a defect of the simulated wafer.

In some embodiments, the recommendation is identified in response to determining that at least one of the first model and the second model has generated values that indicate anomalous operating conditions of the process chamber.

### BRIEF DESCRIPTION OF THE DRAWINGS

FIG. 1 presents a schematic diagram of a digital twin of a process chamber in accordance with some embodiments of the disclosed subject matter.

FIG. 2 presents a block diagram for training an Artificial Intelligence/Machine Learning (AI/ML) model in accordance with some embodiments of the disclosed subject matter.

FIG. 3 presents a block diagram of coupled models of a digital twin in accordance with some embodiments of the disclosed subject matter.

FIGS. 4A and 4B present operations of a processor for generating a digital twin and for use of a digital twin, respectively, in accordance with some embodiments of the disclosed subject matter.

FIG. 5 presents an example computer system that may be employed to implement certain embodiments described herein.

### DETAILED DESCRIPTION

### Terminology

The following terms are used throughout the instant specification:

The terms “semiconductor wafer,” “wafer,” “substrate,” “wafer substrate” and “partially fabricated integrated circuit” may be used interchangeably. Those of ordinary skill in the art understand that the term “partially fabricated integrated circuit” can refer to a semiconductor wafer during any of many stages of integrated circuit fabrication thereon. A wafer or substrate used in the semiconductor device industry typically has a diameter of 200 mm, or 300 mm, or 450 mm. Besides semiconductor wafers, other work pieces that may take advantage of the disclosed embodiments include various articles such as printed circuit boards, magnetic recording media, magnetic recording sensors, mirrors, optical elements, display devices or components such as backplanes for pixelated display devices, micro-mechanical devices and the like. The work piece may be of various shapes, sizes, and materials.

A “semiconductor device fabrication operation” as used herein is an operation performed during fabrication of semiconductor devices. Typically, the overall fabrication process includes multiple semiconductor device fabrication operations, each performed in its own semiconductor fabrication tool such as a plasma reactor, an electroplating cell, a chemical mechanical planarization tool, a wet etch tool, and the like. Categories of semiconductor device fabrication operations include subtractive processes, such as etch processes and planarization processes, and material additive processes, such as deposition processes (e.g., physical vapor deposition, chemical vapor deposition, atomic layer deposition, electrochemical deposition, electroless deposition). In the context of etch processes, a substrate etch process includes processes that etch a mask layer or, more generally, processes that etch any layer of material previously deposited on and/or otherwise residing on a substrate surface. Such etch process may etch a stack of layers in the substrate.

“Manufacturing equipment” refers to equipment in which a manufacturing process takes place. Manufacturing equipment often has a process chamber in which the workpiece resides during processing. Typically, when in use, manufacturing equipment perform one or more semiconductor device fabrication operations. Examples of manufacturing equipment for semiconductor device fabrication include deposition reactors such as electroplating cells, physical vapor deposition reactors, chemical vapor deposition reactors, and atomic layer deposition reactors, and subtractive process reactors such as dry etch reactors (e.g., chemical and/or physical etch reactors), wet etch reactors, and ashers.

An “Artificial Intelligence/Machine Learning (AI/ML) model” as used herein is a trained computational algorithm that has been trained to build a computational model of relationships between data points. A trained AI/ML model can generate outputs based on learned relationships without being explicitly programmed to generate the output using explicitly defined relationships.

Examples of AI/ML models include autoencoder networks (e.g., a Long-Short Term Memory (LSTM) autoencoder, a convolutional autoencoder, a deep autoencoder, a variational autoencoder, and/or any other suitable type of autoencoder network), neural networks (e.g., a convolutional neural network, a deep convolutional network, a recurrent neural network, and/or any other suitable type of neural network), clustering algorithms (e.g., nearest neighbor, K-means clustering, and/or any other suitable type of clustering algorithms), random forests models, including deep random forests, restricted Boltzmann machines, Deep Belief Networks (DBNs), recurrent tensor networks, regressions, and gradient boosted trees.

Note that some AI/ML models are characterized as “deep learning” models. Unless otherwise specified, any reference to AI/ML herein includes deep learning embodiments. A deep learning model may be implemented in various forms, such as by a neural network (e.g., a convolutional neural network). In general, though not necessarily, it includes multiple layers. Each such layer includes multiple processing nodes, and the layers process in sequence, with nodes of layers closer to the model input layer processing before nodes of layers closer to the model output. In various embodiments, one layers feeds to the next, etc.

In various embodiments, a deep learning model can have significant depth. In some embodiments, the model has more than two (or more than three or more than four or more than five) layers of processing nodes that receive values from preceding layers (or as direct inputs) and that output values to succeeding layers (or the final output). Interior nodes are often “hidden” in the sense that their input and output values are not visible outside the model. In various embodiments, the operation of the hidden nodes is not monitored or recorded during operation.

The nodes and connections of a deep learning model can be trained and retrained without redesigning their number, arrangement, etc.

As indicated, in various implementations, the node layers may collectively form a neural network, although many deep learning models have other structures and formats. In some instances, deep learning models do not have a layered structure, in which case the above characterization of “deep” as having many layers is not relevant.

“Physical phenomenon” as used herein refers to observable characteristics or conditions within a particular class. Examples of classes of physical phenomena can include plasma characteristics, thermal characteristics, mechanical or structural characteristics, chemical characteristics, and/or fluid dynamics characteristics.

A “High Fidelity Simulation (HFS) model” refers to values generated using a model or simulation that incorporates various physics-based equations. In an HFS model, the governing equations are derived from first principles of a given physics phenomenon, e.g., conservation of mass and energy in a flow field, force balance in a stress field, etc. The equations can be solved simultaneously in their original Partial Differential Equation (PDE) form by various numerical methods. HFS models can be used, for example, to predict a physical reality of a test condition given variables corresponding to the test condition. Because an HFS model may be associated with a large number of variables, not all of which can be measured, an HFS model is usually calibrated by a given test condition, and subsequently used to predict other test conditions. Note that, when an HFS model is properly calibrated, there should be little difference between outputs of the HFS model and actual test data.

An HFS model can use any suitable technique(s) to model a particular component or a particular location of a process chamber with respect to a particular class of physical phenomenon using explicitly-defined physics laws or equations. For example, an HFS model can simulate thermal characteristics in a particular component (e.g., within a pedestal of an electrostatic chuck (ESC)) and/or in a particular location of a process chamber (e.g., a gap between a showerhead and a pedestal). As another example, an HFS model can simulate structural characteristics of a particular component (e.g., a pedestal of an ESC, one or more screws that attach a pedestal to a base, etc.) and/or in a particular location of a process chamber (e.g., a particular wall, etc.). In some embodiments, an HFS model can use numerical modeling techniques that generate a simulation of a physical phenomena over a series of time steps and/or a series of spatial steps. Examples of techniques that can be used include finite element modeling, finite difference modeling, finite volume modeling, etc.

A “closed-form solution” as used herein refers to an equation, function, or a set of equations or functions that describe a particular physical phenomenon. For example, a closed-form solution can be used to calculate flow through a pipe. As another example, a closed-form solution can be used to calculate flow over a flat plate.

A “digital twin” of a process chamber or other type of digital equipment as used herein refers to a model of an entire process chamber. In some embodiments, a digital twin can be made up of multiple models of different types, where each model represents a different class of physical phenomenon and/or a different location of the process chamber. For example, a digital twin can include a structural model of a showerhead, a thermal model of the showerhead, a chemistry model of a gap between the showerhead and a pedestal, a Computational Fluid Dynamics (CFD) model of the gap between the showerhead and the pedestal, etc. In some embodiments, each model that makes up the digital twin can be one of: 1) a closed-form solution; 2) an AI/ML model; and 3) an HFS model. In other words, a digital twin may be comprised of any of any combinations of a closed-form solution, an AI/ML model, and/or an HFS model.

In some embodiments, the digital twin can include different models (e.g., models of different locations of the process chamber, models of different classes of physical phenomena, and/or different types of models) that have been coupled to form the digital twin. For example, an output of a first model (e.g., an HFS thermal model of a gap between a showerhead and a pedestal) can be used as an input to a second model (e.g., an AI/ML structural model of process chamber walls).

A digital twin of manufacturing equipment may be configured to output any of various types of information about the manufacturing equipment. Such information may include information about a device or partially fabricated device on a substrate processed using the manufacturing equipment, information about one or more components (e.g., a plasma generator, process gas flow inlet, a substrate support, etc.) of the manufacturing equipment, and/or information about process conditions encountered at one or more locations within the manufacturing equipment.

“Predicted wafer characteristics” as used herein can be outputs of a digital twin of a process chamber or other manufacturing equipment. In particular, predicted wafer characteristics can be any suitable characteristics of a simulated wafer fabricated using the digital twin under operating conditions used as inputs to the digital twin.

In some embodiments, predicted wafer characteristics can include “defects” of a simulated wafer. “Defects” as used herein are deviations from the proper functioning of a process, layer, or product. Process defects are deviations from the expected process that can cause malfunctioning of a fabricated device or product. An example of a process defect is scumming, where residue from a photoresist remains on the wafer after stripping. Another example is unwanted bridging, possibly resulting in a short circuit, between elements in a device. Particle defects may be classified by properties such as composition, shape (or morphology), size, and location on a wafer. Defects on semiconductor substrates may originate from one or more sources, often in a substrate processing chamber. Process chamber components such as showerheads, chamber walls, seals, and windows may shed materials in the form of particles, which may produce wafer defects. Additionally, some fabrication processes such as etching processes may result in redeposition or residue left on the substrate, thereby causing defects. Furthermore, defects may result from movement of materials on the substrate, such as reflow of materials during a thermal process, or unintended deposition of particles on the bottom or sides of a wafer that later move and are re-deposited on the top of the wafer.

In some embodiments, predicted wafer characteristics can include indications of “features” of a substrate. A “feature” as used herein is non-planar structure on a substrate surface, typically a surface being modified in a semiconductor device fabrication operation. Examples of features include trenches, vias, pads, pillars, domes, etc. Features may be created by photoresist development, mask definition, lithographic etching, lithographic deposition, epitaxial growth, damascene deposition, and the like. In some embodiments, predicted wafer characteristics can include aspect ratios of features, width dimensions of features, etc.

In some embodiments, predicted wafer characteristics can include a geometric characteristic of a substrate. In some embodiments, a geometric characteristic can include a set of points in space representing the positions of a feature or a group of features, which can include etched features, deposited features, planarized features, etc. Examples of geometric characteristics include a feature's or a collection of features' critical dimension, pitch, depth, aspect ratio, sidewall angle, and the like.

In some embodiments, predicted wafer characteristics can include an optical or chemical characteristic of a substrate or a particular feature or layer on a substrate. Examples of optical or geometric characteristics of a substrate, feature, or layer include extinction coefficient, refractive index, chemical composition, atomic composition, and the like.

“Coupling” or “coupled” as used herein refers to using an output of one model as an input to another model, or vice versa. Coupling may also refer to executing two or more models in parallel and having their outputs combined or otherwise used together in characterizing manufacturing equipment such as a process chamber or a structure fabricated using a process implemented in the manufacturing equipment. Collectively, in some embodiments, coupled models work in concert to implement a digital twin.

In some embodiments, an HFS model can be coupled to an AI/ML model, and vice versa. In some embodiments, two models can be either “sequentially coupled” or “fully coupled.” “Sequentially coupled” refers to one-way communication from a first model to a second model. For example, an output of the first model can be used as an input to the second model. “Fully coupled” refers to two-way communication between a first model and a second model. For example, an output of the first model can be used as an input to the second model, and, an output of the second model can be used as an input to the first model.

“Predictive maintenance” refers to monitoring and predicting a health status of manufacturing equipment or components of manufacturing equipment based on characteristics of the manufacturing equipment and/or based on the components of the manufacturing equipment. In some embodiments, manufacturing equipment can include systems or sub-systems of a chamber, such as an ESC, a showerhead, a plasma source, a Radio Frequency (RF) generator, and/or any other suitable type of manufacturing system or sub-system). In some embodiments, components of manufacturing equipment can include individual components of a system and/or a sub-system, such as a pedestal, an edge ring of an ESC, a particular valve (e.g., of a gas box which supplies gases to a showerhead), and/or any other suitable component.

In some embodiments, a digital twin can be used for predictive maintenance. For example, in some embodiments, a digital twin can be used to simulate a process chamber that has been deployed and is currently operational. Continuing with this example, the digital twin can be used to simulate the deployed process chamber under different deterioration conditions, such as a typical rate of deterioration of various components due to wear and tear, the deployed process chamber operating with a particular malfunctioning component, etc. Continuing still further with this example, in some embodiments, the digital twin can then be used to generate any suitable predictive maintenance metrics (e.g., a Remaining Useful Life (RUL) of particular components, a Mean Time to Failure (MTTF) of a particular system or sub-system, etc.).

In some embodiments, the digital twin can additionally or alternatively identify any suitable prescriptive maintenance recommendations, which can include one or more recommendations to extend a useful lifetime of a component of the deployed process chamber. For example, in some embodiments, the digital twin can be used to identify a recipe parameter change that is likely to extend a useful life of a particular component, such as a pedestal of an ESC. As another example, in some embodiments, the digital twin can be used to identify a component that can be replaced to extend the life of a different component that is likely to fail.

### Overview

A digital twin for a process chamber or other manufacturing equipment is described herein. A digital twin can include multiple models that can be coupled together to form the digital twin. For example, the multiple models can include models of different systems, sub-systems, components, and/or locations of the process chamber, such as a pedestal of an electrostatic chuck (ESC), a showerhead, a gap between a showerhead and the pedestal, a chamber wall, a surface of a simulated wafer being fabricated by the process chamber, a particular pipe, etc. Additionally, each model can represent a particular class of physical phenomena, such as thermal characteristics, plasma characteristics, structural characteristics, chemistry and chemical reactions, and/or fluid dynamics.

In some implementations, a digital twin comprises multiple models, each characterized by at least the following characteristics: a) a type of computational tool; b) a class of physical phenomenon that is predicted; and c) a location within the process chamber or other manufacturing equipment represented by the digital twin.

The type of computational tool describes the logical structure of computational components and/or operations that make up the model. In various embodiments, a model included in the digital twin can be one of the following types of computational tool: 1) AI/ML; 2) HFS; and 3) a closed-form salutation. For example, for a location and for a particular class of physical phenomena in which conditions change over relatively short time-scales or small spatial scales, an HFS model can be used. Particular examples in which HFS models may be used can include a plasma model of a gap between a pedestal and a showerhead, a chemistry model of a wafer surface, etc.

As another example, for a location and for a particular class of physical phenomena in which conditions are relatively stable over time and/or over spatial positions, an AI/ML model can be used. Particular examples in which AI/ML models may be used can include a thermal model of a chamber wall, etc. As yet another example, for a location and for a particular class of physical phenomena that may be too complicated to simulate using an HFS model, an AI/ML model may trained using physical sensor measurements and/or computationally generated training data that represents physical conditions within manufacturing equipment during operation. A particular example is a thermal model that simulates temperature flux or heat transfer within a ceramic pedestal that includes an embedded mesh.

As still another example, for some equipment locations and physical phenomena, the characteristics of the phenomena can be accurately and reliably represented by a simple equation or other closed-form solution. In such cases, the closed-form solution may be used in lieu of a HFS or an AI/ML representation of a physical phenomenon and thereby conserve computational resources for other, more computationally intensive models required to predict more complicated physical phenomena. Particular examples of physical phenomena where a closed-form solution can be used can include flow through a pipe, flow over a flat plate, plate bending, etc.

By combining different model types for different locations and classes of physical phenomena within the digital twin, the digital twin can accurately simulate the process chamber while balancing computational resource use. For example, the digital twin can use computationally-intensive HFS models for locations of the process chamber and/or for dynamically changing physical phenomena, while reserving computational resources by using less intensive AI/ML models and/or closed-form solutions to model locations and/or physical phenomenon that can be accurately modeled by AI/ML models or closed-form solutions.

A digital twin of a process chamber can be used for any suitable application. For example, a digital twin can be used to evaluate or validate a design of a system, sub-system, or component, such as a new potential design. As another example, a digital twin can be used to evaluate or validate a recipe or process to be implemented by the process chamber, such as a change in process gases used, a change in setpoints, etc. As yet another example, a digital twin can be used to perform predictive maintenance by simulating a currently deployed process chamber. As a particular example, by simulating a currently deployed process chamber, the digital twin can be used to identify likely future failures of the deployed process chamber. Moreover, the digital twin can be used to identify recommendations that may mitigate a likely future failure.

### Digital Twins of Semiconductor Manufacturing Equipment

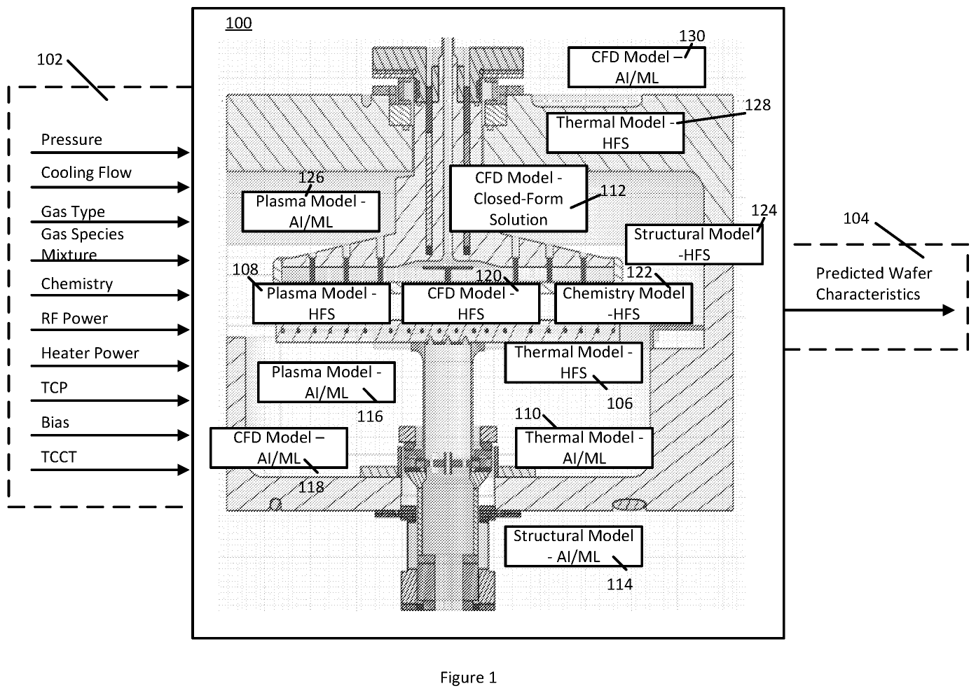

Turning to FIG. 1, an example schematic diagram of a digital twin 100 of a process chamber is shown in accordance with some embodiments of the disclosed subject matter.

Digital twin 100 can be a model of a substantial portion of a process chamber or an entire process chamber. That is, in some embodiments, digital twin 100 can include models of different systems or sub-systems of the process chamber that encompass different classes of physical phenomena that occur in the process chamber.

In some embodiments, digital twin 100 can take inputs 102 and can generate predicted substrate characteristics 104 as an output. In some embodiments, digital twin 100 can generate information about one or more components of a process chamber, and/or about one or more process conditions that occur during processing a substrate in the process chamber.

In some embodiments, inputs 102 can include any suitable parameter values that correspond to controls of a process chamber modeled by digital twin 100. For example, as shown in FIG. 1, inputs 102 can include various process chamber settings such as chamber pressure, coolant flow (or other thermal flux control), gas type, gas species mixture composition, chemistry characteristics, RF power, heater power, Transformer Coupled Plasma (TCP) settings, Bias, Transformer Coupled Capacitive Tuning (TCCT) circuit settings, and/or any other suitable inputs. Note that the inputs shown in FIG. 1 are merely exemplary. In some embodiments, any of the inputs shown in FIG. 1 can be omitted. Additionally or alternatively, in some embodiments, any other parameters not shown in FIG. 1 can be included in inputs 102, such as inputs related to pre-processed substrate conditions (e.g., incoming variability of a stack, structure, and/or substrate), inputs related to a sequence of process steps (e.g., a sequence of steps of a process prior to a current step), inputs related to a system state, inputs related to a configuration of hardware or software, etc.

Predicted wafer characteristics 104 can be any suitable predicted characteristics of a simulated wafer fabricated by a process chamber represented by digital twin 100. In some embodiments, the predicted characteristics can include information about features of the simulated features, such as etched features, deposited features, planarized features, etc. For example, feature information can include geometric information that indicates aspect ratios, widths, heights, etc, of features. As a more particular example, the geometric information can include an etch depth, a side wall angle, etc. In some embodiments, the predicted characteristics can include information about defects of the simulated wafer, such as a location of a defect, a type of defect, etc.

In some embodiments, predicted wafer characteristics 104 can be used for any suitable purposes, such as: 1) design validation; 2) process validation; and/or 3) predictive maintenance.

Design validation can be validation of particular systems, sub-systems, or components of the process chamber. For example, design validation can include a validation of a structure of a system (e.g., a showerhead, an ESC, a plasma source, an RF generator, etc.), a sub-system (e.g., a pedestal of an ESC, etc.), or a component (e.g., an edge ring of an ESC, a valve of a gas box, etc.). In some embodiments, design validation can be used to validate a potential new structure, such as a newly designed pedestal of an ESC, a potential modification to a showerhead (e.g., to include more holes, to include holes of different sizes or in a different pattern, etc.), and/or any other suitable potential new structure. For example, in some embodiments, design validation can be used to evaluate a potential new structure for a system, sub-system, or component of a process chamber by evaluating predicted wafer characteristics 104 generated using the potential new structure.

Process validation can be validation of a process or recipe used by a process chamber. For example, process validation can include a validation of a change to a process or recipe currently used by the process chamber. In some embodiments, example process or recipe changes can include changes in applied temperatures (e.g., a temperature applied to a pedestal), changes in process gases used (e.g., changes in gas compositions or gas mixture ratios), changes in plasma pulse profiles, etc. In some embodiments, process validation can be used to evaluate a potential modification to a process or recipe by evaluating predicted wafer characteristics 104 generated using the modified process or recipe.

Predictive maintenance can include identifying systems, sub-systems, or components of a process chamber that are likely to fail and/or a time period during which systems, sub-systems, or components of a process chamber are likely to fail (e.g., that a pedestal of an ESC is likely to chip or fracture within a particular time period, that a showerhead is likely to fail within a particular time period, that a particular valve is likely to fail within a particular time period, etc.). Additionally or alternatively, in some embodiments, predictive maintenance can include identifying a likely cause of failure for a particular system, sub-system, or component of a process chamber. For example, a likely cause of a failure of a pedestal of an ESC can be identified as anomalous temperature gradients or anomalous temperature fluxes. In some embodiments, likely failures and/or likely causes of failures can be identified based on values of individual models of digital twin 100. For example, values of a thermal model of a pedestal of an ESC can be identified as being outside of normal operating ranges. Continuing with this example, the pedestal can be identified as likely to fail within a particular time range due to the anomalous values of the thermal model of the pedestal.

In some embodiments, predictive maintenance can include a prediction that fabricated wafers are likely to include defects, for example, due to a likely failure of a particular system, sub-system, or component of a process chamber. For example, the prediction can indicate that fabricated wafers will include defects due to excess particles because of a crack, abrasion, or other failure of a showerhead or other component in the interior of the process chamber. In some embodiments, such predictions can be generated based on predicted wafer characteristics 104 that indicate defects under particular operating conditions of digital twin 100.

In some embodiments, predictive maintenance can additionally include a recommendation to mitigate a likely failure of a system, sub-system, or component and/or to prevent defects of fabricated wafers. For example, in an instance in which predicted wafer characteristics 104 indicate likely defects in a wafer, a recommendation to change a parameter of a recipe used to fabricate the wafer can be identified. As a more particular example, a recommendation to change an operating temperature, change a gas flow rate, etc, can be identified and presented.

As shown in FIG. 1, digital twin 100 can include multiple models of different systems or sub-systems of the process chamber represented by digital twin 100. For example, digital twin 100 can include models of a pedestal of an ESC, a showerhead, chamber walls, a gap between the showerhead and the pedestal, and/or any other suitable systems or sub-systems. In some embodiments, each model can be one of: 1) an AI/ML model; 2) an HFS model; and 3) a closed-form solution.

In some embodiments, each model included in digital twin 100 can represent a particular class of physical phenomena. Example classes of physical phenomena can include: 1) plasma characteristics within operating equipment; 2) fluid dynamics characteristics within operating equipment; 3) thermal characteristics of equipment components; 4) structural characteristics of equipment components; and 5) chemistry characteristics or chemical reactions and/or un-reacting chemical species within operating equipment. Some or all of the models may represent only one or more regions within the manufacturing equipment. Such models may have geometric boundaries defining a limited region within the manufacturing equipment. In some cases, such boundaries are represented within a model by boundary conditions.

In some embodiments, plasma characteristics can include plasma properties, such as plasma temperature, potential, density, composition (e.g., ions versus electrons), and/or plasma properties. In some embodiments, plasma characteristics may be determined as a function of time, for example, based on a plasma pulsing profile. In some embodiments, plasma characteristics may be particularly relevant for locations of a reactor such as between a showerhead and a pedestal of an ESC, in a parasitic outside gap region, and/or any other suitable location.

In some embodiments, fluid dynamics characteristics can include flow from a gas inlet, such as a showerhead, and/or fluid flow around components (e.g., a showerhead, a pedestal, chamber walls, etc.).

In some embodiments, thermal characteristics can include thermal properties of any gases, solids, and/or plasmas in a reactor. For example, thermal properties can include thermal or heat transfer within a component such as a substrate pedestal or a process gas showerhead, or within an open area of the equipment such as a gap between a showerhead and pedestal.

In some embodiments, structural characteristics can include mechanical stresses, forces, pressures, etc, of different components and/or of boundaries between components of the reactor. For example, structural characteristics can include pressures on a particular valve, stresses on a wafer being fabricated, forces on a chamber wall, etc.

In some embodiments, chemistry characteristics can include reaction kinetics at a substrate surface and/or on an equipment component such a chamber wall, a showerhead, or a substrate pedestal. In some embodiments, chemistry characteristics can include equilibrium or non-equilibrium concentration of one or more chemical species at a substrate surface and/or on an equipment component such a chamber wall, a showerhead, or a substrate pedestal. In some embodiments, chemistry characteristics can include mass transfer characteristics of one or more chemical species to or from a substrate surface and/or on an equipment component such a chamber wall, a showerhead, or a substrate pedestal.

As shown in FIG. 1, digital twin 100 can include individual models of different locations of the process chamber, each being a particular model type and representing a particular class of physical phenomena. For example, digital twin 100 can include an HFS thermal model of a pedestal 106, an HFS plasma model of a gap between a showerhead and the pedestal 108, an AI/ML thermal model of chamber walls 110, a closed-form solution CFD model of flow through a pipe 112, an AI/ML structural model of a chamber wall 114, an AI/ML plasma model of an area adjacent to a pedestal 116, an AI/ML CFD model of an area adjacent to a pedestal 118, an HFS CFD model of the gap between the showerhead and the pedestal 120, an HFS chemistry model of the gap between the showerhead and the pedestal 122, an HFS structural model of a chamber wall 124, an AI/ML plasma model of an area adjacent to a showerhead 126, an HFS thermal model of a chamber wall 128, and/or an AI/ML CFD model of a chamber wall 130. Note that assignment of models shown in digital twin 100 as having particular model types, representing particular classes of physical phenomenon, and being used for particular locations or systems of the process chamber is merely exemplary. In some embodiments, model types and classes of physical phenomena can be any suitable type(s) and combinations.

In some embodiments, digital twin 100 can use an AI/ML model to simulate a particular location, system, or subsystem of a process chamber with respect to a particular class of physical phenomenon that is, for example, relatively stable over time. For example, an AI/ML model can be used in an instance in which values of parameters associated with the class of physical phenomenon do not vary by a substantially large magnitude within a relatively short time period (e.g., within a nanosecond, within a millisecond, etc.). As a more particular example, an AI/ML model can be used to simulate structural effects of a chamber wall, plasma conditions, thermal effects, and/or fluid dynamics in any of various regions outside the pedestal-showerhead gap of a process chamber.

Additionally or alternatively, in some embodiments, digital twin 100 can use an AI/ML model to simulate a particular location or system of a process chamber and with respect to a particular class of physical phenomenon for which an HFS model cannot produce results correctly. For example, an AI/ML model can be used to simulate thermal characteristics of a ceramic pedestal that includes an inner mesh. In some such embodiments, the AI/ML model can be trained using physical sensor measurements where the sensors are placed at various physical positions of the process chamber.

In some embodiments, digital twin 100 can use an HFS model to simulate a particular location or system of a process chamber with respect to a particular class of physical phenomenon that changes over short time-scales. For example, HFS models can be used to simulate plasma, thermal, and/or chemistry characteristics within a gap between a showerhead and a pedestal, as shown in FIG. 1.

In some embodiments, digital twin 100 can use a closed-form solution that includes one or more closed-form physics equations in a situation where such closed-form physics equations are known. Examples of situations in which closed-form solutions can be used include flow over a flat plate, flow through a pipe, plate bending, plasma conductivity, electron temperature, sheath thickness under certain operating conditions, etc.

In some embodiments, a type of model included in digital twin 100 that is used for a particular location and for a particular class of physical phenomenon can be switched. For example, in an instance in which an HFS model is used for a particular location or system of a process chamber (e.g., a pedestal, chamber walls, etc.), a trained AI/ML model of the particular location or system of the process chamber, which represents the same class of physical phenomenon, can replace the HFS model. In this manner, models included in digital twin 100 can be modular. This may be appropriate when, for example, new models are developed or one or a few components of manufacturing equipment are changed, but other components remain unchanged.

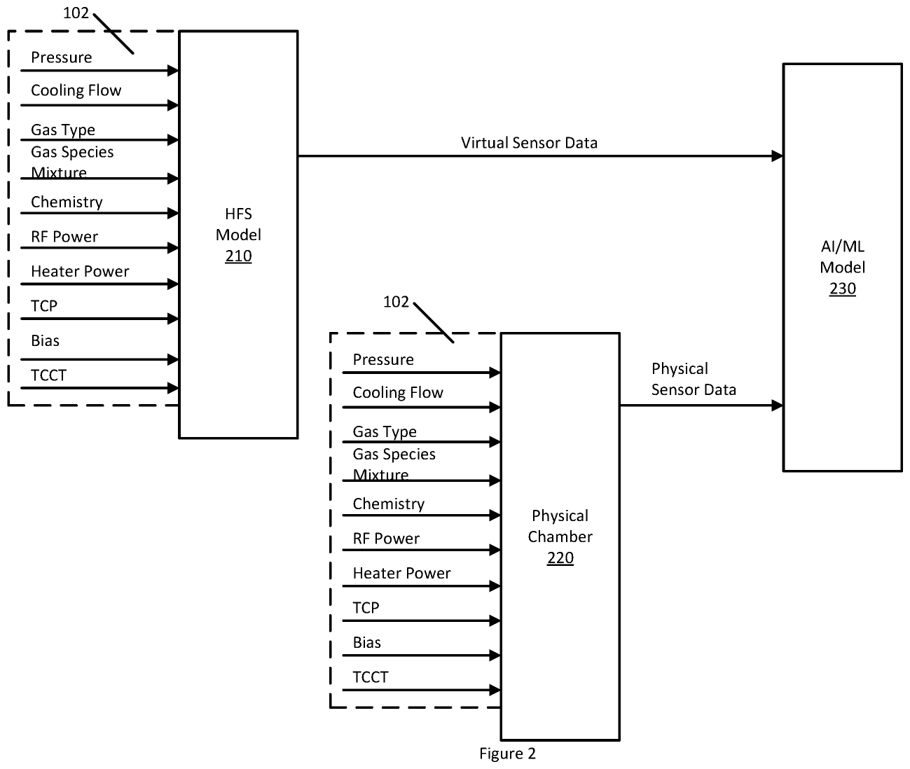

Turning to FIG. 2, a schematic diagram for training AI/ML models is shown in accordance with some embodiments of the disclosed subject matter.

As illustrated, an AI/ML model 230 can be trained using virtual sensor data generated by an HFS model 210 and/or physical sensor data measured using a physical chamber 220.

Note that, in some embodiments, AI/ML model 230) and HFS model 210 can correspond to the same class of physical phenomenon (e.g., thermal, plasma, chemistry, CFD, and/or structural) and can represent the same location or system of a process chamber.

When available, training data from sensors in a functioning physical system are used. However, in many instances, insufficient physical training data is available to successfully train a trustworthy AI/ML model. In some embodiments, this challenge is met by using HFS model 210 or other model to generate virtual sensor data in any suitable manner. For example, in some embodiments, HFS model 210 can use inputs 102 to simulate a physical phenomenon, such as thermal flux or heat flow at sequential timesteps and/or spatial steps to generate simulated time series data at a group of virtual sensors. As a more particular example, in an instance in which HFS model 210 is a thermal model, HFS model 210 can generate a simulated time series of simulated thermocouple measurements from a group of virtual thermocouples at different locations. As another more particular example, in an instance in which HFS model 210 is a structural model, HFS model 210 can generate a simulated time series of pressure. force, etc, measurements from a group of virtual sensors simulated at different locations. As another more particular example, in an instance in which HFS model 210 is a chemistry model, HFS model 210 can generate a simulated time series of chemical reaction states based on molecular dynamics. Note that, in some embodiments, the virtual training data is generated for manufacturing equipment locations that are not accessible—at least not practically—using physical sensors. For example, it is often not practical to collect physical data in the gap between a pedestal and showerhead during a plasma reaction.

Physical chamber 220 can generate physical sensor data in any suitable manner. For example, in some embodiments, physical sensors that measure any suitable type of physical phenomena (e.g., temperature, pressure, force, power, etc.) can be located at any suitable physical locations of a process chamber. In some embodiments, physical sensor data can be any suitable time series data that is measured at any suitable frequency or timestep.

Note that, although inputs 102 are shown as inputs to both HFS model 210 and physical chamber 220, in some embodiments, inputs used by HFS model 210 can be different than inputs used by physical chamber 220, which are generally controllable parameters of the physical chamber. For example, in some embodiments, HFS model 210 may take, as inputs, a subset of inputs 102 that are relevant to the class of physical phenomena represented by HFS model 210 and/or that are relevant to the location or process chamber system modeled by HFS model 210.

AI/ML model 230 can be trained in any suitable manner. For example, in some embodiments, a training set can be constructed that includes training samples generated using the virtual sensor data from HFS model 210 and/or physical sensor data generated using physical chamber 220. As a more particular example, for a particular training sample, input values can correspond to values of inputs 102 and target outputs can correspond to sensor data, whether virtual (i.e., when a training sample is based on HFS model 210) or physical (i.e., when a training sample is based on physical sensor data from physical chamber 220).

Note that, in some embodiments, AI/ML model 230 can be trained using only virtual sensor data from HFS model 210 or only physical sensor data generated using physical chamber 220. For example, in an instance in which AI/ML model 230 represents a location or system and a class of physical phenomena that is too complex to have an associated HFS model (e.g., thermal characteristics of a ceramic pedestal with an embedded mesh), AI/ML model 230 can be trained using only physical sensor data. Conversely, in an instance in which AI/ML model 230 represents a location or system and a class of physical phenomena for which physical sensor data cannot be measured (e.g., because a physical sensor cannot be placed at the location of the process chamber), AI/ML model 230 can be trained using only virtual sensor data.

Note that, in some embodiments, a portion of the physical sensor data can be reserved to validate AI/ML model 230 after AI/ML model 230 has been trained using the virtual sensor data and/or a remaining portion of the physical sensor data.

Additionally, note that, in some embodiments, HFS Model 210 can generate virtual sensor data at relatively short timescales (e.g., picoseconds, nanoseconds, etc.) and/or at relatively small spatial scales (e.g., angstroms, nanometers, etc.). In some embodiments, the short timescale and/or small spatial scale data can be used to train AI/ML model 230, which can, once trained, generate predicted outputs on a longer timescale (e.g., milliseconds, seconds, minutes, hours, etc.) and/or at a larger spatial scale (millimeters, centimeters, etc.) that correspond to timescales or spatial scales of interest in full operation of a process chamber. For example, an HFS chemistry model may generate simulated chemical reaction kinetics at a timescale of picoseconds (e.g., to simulate wafer reaction chemistry). Continuing with this example, the HFS chemistry model may be used to train a corresponding AI/ML chemistry model that generates outputs at a relatively longer timescale (e.g., seconds) that can be used as inputs to other models of the digital twin.

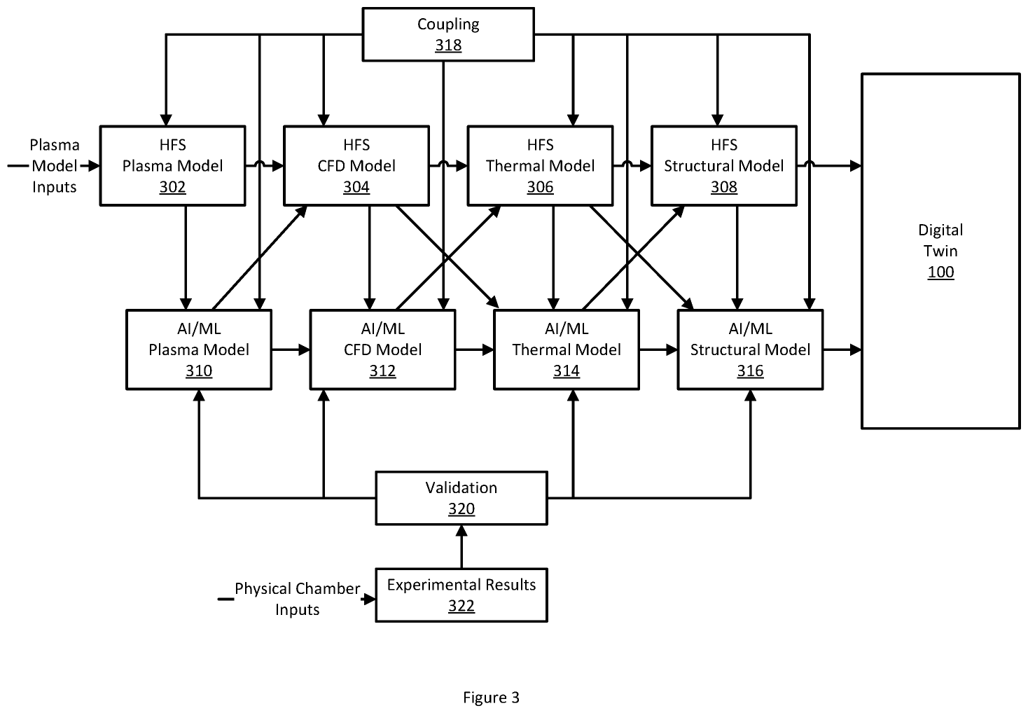

Turning to FIG. 3, a block diagram of coupled models to generate a digital twin of a process chamber is shown in accordance with some embodiments of the disclosed subject matter.

As described above, digital twin 100 can include multiple models, each associated with a location or system of the process chamber, representing a particular class of physical phenomena, and being of a particular type (i.e., HFS, AI/ML, or closed-form solutions).

For example, as shown in FIG. 3, digital twin 100 can include HFS plasma model 302, HFS CFD model 304, HFS thermal model 306, HFS structural model 308, AI/ML model 310, AI/ML CFD model 312, AI/ML thermal model 314, and/or AI/ML structural model 316.

Note that, in some embodiments, various models that can be incorporated in digital twin 100 are not shown in FIG. 3. For example, in some embodiments, one or more closed-form solutions can be included in digital twin 100, which are not shown in FIG. 3. As another example, additional HFS models and AI/ML models beyond what are shown in FIG. 3 may be included. As a more particular example, HFS plasma model 302 may correspond to a particular system or location of the process chamber, such as a gap between a pedestal and a showerhead. Continuing further with this particular example, in some embodiments, a second HFS plasma model 302, that corresponds to a different system or location of the process chamber (e.g., within a pipe, etc.) may be included in digital twin 100.

Additionally, note that, in some embodiments, any of models 302-316 can be omitted. For example, in an instance in which AI/ML plasma model 310 adequately represents plasma characteristics for a particular location or system of a process chamber, HFS plasma model 302 for the same location or system of the process chamber can be omitted. As another example, in an instance in which AI/ML plasma model 310 cannot adequately represent plasma characteristics for a particular location or system of a process chamber, AI/ML plasma model 310 can be omitted.

As illustrated in FIG. 3, outputs from one model can be used as inputs for another model. For example, AI/ML model 330 can receive, as inputs, outputs generated by HFS plasma model 302. As another example, AI/ML CFD model 312 can receive, as inputs, outputs generated by HFS CFD model 304 and/or AI/ML plasma model 310. Note that, in some embodiments, an AI/ML model can take, as inputs, outputs generated by another AI/ML model, an HFS model, and/or a closed-form solution. Similarly, an HFS model can take, as inputs, outputs generated by another HFS model, an AI/ML model, and/or a closed-form solution.

Note that the model connections shown in FIG. 3 are merely exemplary. In some embodiments, a model can take, as inputs, outputs generated by any suitable number of models (e.g., one, two, five, ten, and/or any other suitable number). Additionally, note that two models can be either sequentially coupled or fully coupled. For example, in an instance in which two models are sequentially coupled, a second model can be configured to take, as inputs, outputs generated by a first model. Continuing with this example, in an instance in which the two models are sequentially coupled, the first model does not take, as inputs, outputs generated by the second model. Conversely, in an instance in which two models are fully coupled, the first model can generate outputs that are taken as inputs by the second model, and can additionally take, as inputs, outputs generated by the second model.

Additionally, note that, in some embodiments, an AI/ML model can be used to match an output of a first HFS model to an expected input of a second HFS model. For example, HFS plasma model 302 may generate a set of outputs, a subset of which are required by HFS CFD model 304. Continuing with this example, some outputs of HFS plasma model 302 may not be in a format required by HFS CFD model 304.

In some embodiments, coupling of one model to another can be implemented using logic such as that represented in a coupling block 318. In some embodiments, coupling block 318 can perform any suitable function(s) that allow a first model to provide outputs to a second model for use as inputs by the second model. For example, in some embodiments, coupling block 318 can determine (e.g., based on user-specified instructions, and/or in any other suitable manner) that a second model is to take, as inputs, outputs generated by the first model. Continuing with this example, coupling block 318 can wait until the first model generates the indicated outputs, such as temperature values at particular time steps and spatial locations, gas species compositions at particular time steps and spatial locations, etc. Continuing still further with this example, in response to receiving the indicated outputs, coupling block 318 can transmit the outputs to the second model. As a specific example, coupling block 318 can call any suitable function(s) associated with the second model using the outputs of the first model as input parameters with respect to the function call(s).

It should be noted that any of the models included in a digital twin can execute in parallel or in series with other models in the digital twin. Coupling block 318 can be configured to transmit model results between models such that models can operate in parallel and/or in series.

Note that, in some embodiments, an architecture of digital twin 100 that specifies types of models used to represent each location or system of the process chamber with respect to each class of physical phenomena can be designed or specified in any suitable manner. For example, in some embodiments, the architecture can be specified using a user interface that allows a user to select particular models (e.g., an HFS plasma model of a gap between a showerhead and a pedestal, an AI/ML model of thermal characteristics of a pedestal, etc.) for inclusion in digital twin 100. In some such embodiments, coupling of different models included in digital twin 100 can additionally be specified via the user interface. For example, particular pairs of models can be indicated as fully coupled or sequentially coupled. Additionally, in some embodiments, particular outputs that are to be waited for by coupling block 318 can be specified via such a user interface.

In some embodiments, validation block 320 can validate performance of the AI/ML models when coupled to other models within digital twin 100. For example, in some embodiments, validation block 320 can validate a performance of AI/ML thermal model 314 when it receives inputs from other models, such as AI/ML CFD model 312, HFS CFD model 304, HFS thermal model 306, and/or any other suitable models.

In some embodiments, validation can be performed using experimental results 322. In some embodiments, validation block 320 can be configured to calibrate one or more AI/ML models to match experimental results 322. For example, in some embodiments, a Design of Experiments (DOE) technique can be used to find a combination of variables that best match experimental results 322. In some embodiments, the combination of variables that best match experimental results 322 can be identified using an optimization algorithm. In some embodiments, an identified combination of variables can be further verified in connection with hardware test conditions, for example, to ensure that identified variables and/or values of variables are physically possible under certain hardware test conditions.

In some cases, a digital twin of a manufacturing equipment is generated by identifying physical phenomena and locations within the equipment where those phenomena are to be represented. This may involve, in a sense, mapping physical phenomena to particular locations within the equipment. Note that not all physical phenomena need be represented at all locations within the equipment. For example, plasma conditions or fluid dynamics need not be modeled in the chamber wall and/or in locations within a chamber where they may have little impact on the process conducted on a substrate. After the physical phenomena and locations are chosen/mapped, the types of model for each combination of location and phenomena are chosen. As indicated, this may involve choosing the least computationally intensive model type available to represent the process with a level of fidelity sufficient for the digital twin to accurately generate its outputs. With the combinations of phenomena/locations/model types selected, the individual models are generated. In some cases, this may involve selecting and parameterizing HFS and/or closed form functions that accurately predict the relevant physical conditions. In some cases, this involves obtaining training data and then training and validating AI/ML models. Finally, appropriate coupling logic may be developed for allowing all the models to execute in concert to collectively produce the digital outputs. In some embodiments. all models, including those that do not necessarily require training, are operated in concert as part of the training process. For example, the overall output of the digital twin may be used to calculate error in the current version(s) of the model(s) being trained.

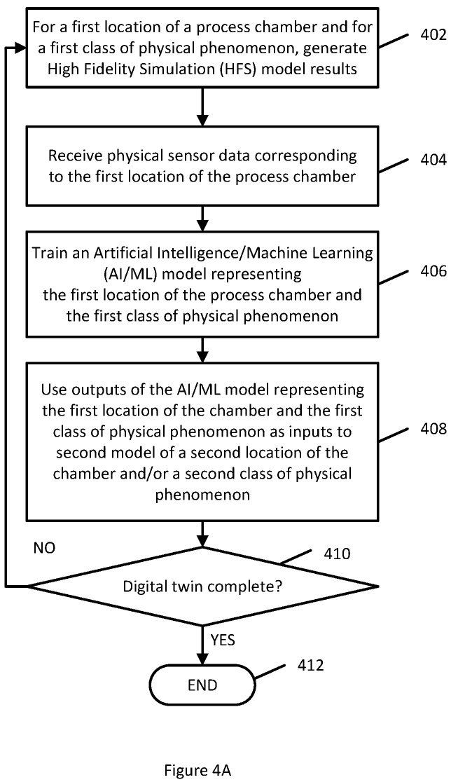

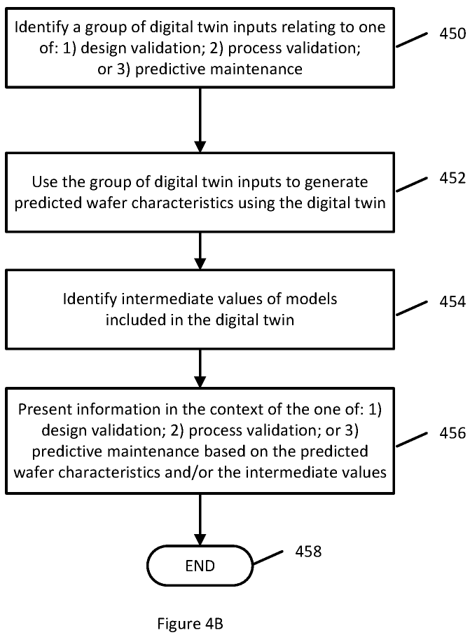

Turning to FIG. 4A, an example of a process for generating a digital twin for a process chamber is shown in accordance with some embodiments of the disclosed subject matter. At 402, for a first location of the process chamber and for a first class of physical phenomenon. HFS model results can be generated. As described above, the first location of the process chamber can be any suitable location, system, or sub-system of the process chamber, such as a pedestal of an ESC, a showerhead, a gap between the showerhead and the pedestal, a wafer being fabricated, etc. The first class of physical phenomenon can be any suitable class of physical phenomenon, such as thermal characteristics, chemistry characteristics. CFD characteristics, structural characteristics, and/or plasma characteristics.

The HFS model results can be generated in any suitable manner. For example, in some embodiments, the HFS model results can include time series data that indicates simulated values at a series of timesteps. As another example, in some embodiments, the HFS model results can include simulated values at different simulated spatial locations, such as spatial locations corresponding to virtual sensors.

At 404, physical sensor data corresponding to the first location of the process chamber can be received. As described above in connection with FIG. 2, the physical sensor data can include any suitable measurements, such as temperature measurements, force measurements, pressure measurements, gas flow measurements, optical emissions measurements, spectroscopy measurements, and/or any other suitable measurements. The physical sensor data can be collected from physical sensors located at any suitable physical positions of the process chamber.

At 406, an AI/ML model representing the first location of the process chamber and the first class of physical phenomenon can be trained. As described above in connection with FIG. 2, the AI/ML model can be trained using the HFS model results and/or the physical sensor data. For example, in some embodiments, a training set can be created that includes the HFS model results and/or the physical sensor data, and the training set can be used to train the AI/ML model.

At 408, outputs of the AI/ML model representing the first location of the process chamber and the first class of physical phenomenon can be used as inputs to a second model of a second location of the process chamber and/or of a second class of physical phenomenon. Note that, in some embodiments, the second model of the second location of the process chamber and/or the second class of physical phenomenon can be an AI/ML model, an HFS model, or a closed-form solution.

In some embodiments, outputs of the AI/ML model representing the first location of the process chamber and the first physical phenomenon can be provided to the second model in any suitable manner. For example, in some embodiments, the outputs of the AI/ML model can be provided to a coupling block or module that receives the outputs of the AI/ML model and transmits the outputs to the second model for use by the second model as inputs to the second model.

At 410, a determination of whether the digital twin is complete can be made. The determination of whether the digital twin is complete can be made based on any suitable information and in any suitable manner. For example, the digital twin can be determined to be complete in response to determining that a model for each location or system in a set of process chamber locations and/or systems has been included in the digital twin. In some embodiments, the set of process chamber locations and/or systems can include any suitable number of chamber locations and/or systems that have been designated as required for an accurate digital twin model of the process chamber.

Note that, in some embodiments, the digital twin can be determined to be complete when models included in the digital twin have been coupled.

In response to determining, at 410, that the digital twin is not complete (“no” at 410), the process can loop back to 402 and can generate HFS model results for a different location of the process chamber and/or for a different class of physical phenomenon.

Conversely, in response to determining, at 410, that the digital twin is complete (“yes” at 410), the process can end at 412.

Turning to FIG. 4B, an example of a process for using a digital twin is shown in accordance with some embodiments of the disclosed subject matter. In particular, FIG. 4B shows a process for using a digital twin in the context of one of: 1) design validation; 2) process validation; or 3) predictive maintenance. Note that predictive maintenance is applicable to process chambers that have already been deployed and that are in use. By contrast, design validation and/or process validation may be applicable to process chambers or processes that are being designed and are not currently deployed.

At 450, a group of digital twin inputs relating to one of: 1) design validation; 2) process validation; or 3) predictive maintenance can be identified.

In some embodiments, inputs relating to design validation can include structural specifications of a new or modified system, sub-system, or component being evaluated. Additionally, in some embodiments, inputs relating to design validation can include structural specifications of other systems, sub-systems, or components of the process chamber that are not being evaluated. For example, in an instance in which a potential new pedestal of an ESC is being evaluated, the inputs can include specifications of the potential new pedestal as well as specifications of other systems, sub-systems or components of the process chamber that will remain unchanged.

In some embodiments, inputs related to process validation can include information indicating a process or recipe that is to be implemented in a process chamber. For example, the information can include setpoints (e.g., temperature setpoints, pressure setpoints, etc.), gas mixture compositions, gas flow rates, etc.

In some embodiments, inputs related to predictive maintenance can include specifications of a deployed process chamber and/or specifications of a recipe implemented on a deployed reactor. In some embodiments, specifications of a deployed process chamber can include specifications of systems, sub-systems, and/or components of the process chamber, such as model numbers of particular components, dimensions of any suitable aspects of a system or sub-system (e.g., a size of a pedestal, a thickness of a pedestal, dimensions of a mesh inside a pedestal, a thickness of a chamber wall, etc.), materials used in a particular system or sub-system, and/or any other suitable specification information. In some embodiments, specifications of a recipe can include information indicating setpoints used in the recipe (e.g., a temperature setpoint, a pressure setpoint, etc.), compositions of gases used, gas flow rates, etc.

At 452, the group of digital twin inputs can be used to generate predicted wafer characteristics using the digital twin. In some embodiments, the predicted wafer characteristics can correspond to a wafer that would be fabricated using the process chamber when using the digital twin inputs.

At 454, intermediate values of models included in the digital twin can be identified. In some embodiments, intermediate values of models can include values generated by any model included in the digital twin corresponding to any location of the process chamber and/or representing any class of physical phenomena. For example, values can be generated by a thermal model of a pedestal, a thermal model of a showerhead, a plasma model of a gap between the pedestal and the showerhead, a structural model of chamber walls, a fluid dynamics model of the gap between the pedestal and the showerhead, a chemistry model of a wafer surface, and/or values from any other suitable model. Note that models can be any of AI/ML, HFS, and/or closed-form solutions.

As a more particular example, values of a thermal model of a pedestal can include time series values that include simulated temperature measurements associated with various positions of the pedestal.

As another more particular example, values of a plasma model of the gap between the pedestal and the showerhead can include time series values that indicate simulated plasma temperature, density, potential, and/or composition measurements at various positions in the gap between the pedestal and the showerhead.

At 456, the information can be presented in the context of the one of: 1) design validation; 2) process validation; and 3) predictive maintenance. In some embodiments, the information can be generated and presented based on the predicted wafer characteristics and/or the intermediate values of models included in the digital twin.

For example, in an instance in which the predicted wafer characteristics are used for design validation or process validation, an indication of whether the predicted wafer characteristics include particular defects can be presented. As another example, an indication of whether a wafer corresponding to the predicted wafer characteristics would fail any suitable quality criteria can be indicated.

As another example, in an instance in which predicted maintenance information is presented, intermediate values of models included in the digital twin can be used to identify likely failures of systems, sub-systems, or components of the simulated process chamber. As a more particular example, in response to determining that values of a thermal model of a pedestal are outside normal operating conditions, a likely failure of the pedestal can be identified. As another more particular example, in response to determining that values of a plasma model of a gap between the pedestal and a showerhead are outside normal operating conditions, a likelihood of defects in a fabricated wafer can be identified.

In some embodiments, in response to identifying a likely failure, the digital twin can be used to identify one or more recommendations to mitigate the likely failure. For example, in some embodiments, a change to a parameter of a recipe can be identified. As another example, in some embodiments, a replacement of a component of the process chamber can be identified. In some such embodiments, the recommendation can be evaluated by re-running the digital twin with updated input values that represent the modification.

The process can end at 458.

### Applications

The techniques described herein for generating a digital twin of a process chamber can be used to generate a digital twin that balances accurate simulation of a process chamber with use of computational resources. For example, model types of individual models (e.g., of particular locations of the process chamber and/or representing particular classes of physical phenomena) can be selected such that computationally-intensive models, such as HFS models, are used in contexts that particularly benefit from the accuracy of an HFS simulation. Conversely, less computationally-intensive models, such as AI/ML models and/or closed-form solutions, can be used in contexts where an HFS model cannot be used (e.g., because the complexity of the context cannot be simulated with an HFS model), in contexts where an AI/ML model can be trained, and/or in contexts that can be represented using one or more closed-form solutions.

By coupling models of different locations of a process chamber and representing different classes of physical phenomena such that the different models interact with each other, the complexity of an entire process chamber can be represented by the digital twin.

By simulating an entire process chamber, new designs of process chamber systems, sub-systems, and/or components, as well as new processes or recipes, can be evaluated prior to deployment. Simulation of designs and/or processes can allow potential problems in a design or process to be identified prior to costly failures occurring after deployment.

Additionally, simulation of an entire process chamber can allow potential failures of systems, sub-systems, and/or components of the process chamber to be proactively identified, thereby allowing proactive maintenance to be scheduled, replacement of parts, and/or recipe parameter changes that can mitigate a potential failure. Such predictive maintenance can save costs and reduce downtime of semiconductor manufacturing equipment.

### Context for Disclosed Computational Embodiments

Certain embodiments disclosed herein relate to computational systems for generating and/or using various computational models. Certain embodiments disclosed herein relate to methods for generating and/or using a computational model implemented on such systems. A system for generating a computational model may also be configured to receive data and instructions such as program code representing physical processes occurring during the semiconductor device fabrication operation. In this manner, a computational model is generated or programmed on such system.

Many types of computing systems having any of various computer architectures may be employed as the disclosed systems for implementing computational models and algorithms for generating and/or optimizing such models. For example, the systems may include software components executing on one or more general purpose processors or specially designed processors such as Application Specific Integrated Circuits (ASICs) or programmable logic devices (e.g., Field Programmable Gate Arrays (FPGAs)). Further, the systems may be implemented on a single device or distributed across multiple devices. The functions of the computational elements may be merged into one another or further split into multiple sub-modules.

In some embodiments, code executed during generation or execution of a computational model on an appropriately programmed system can be embodied in the form of software elements which can be stored in a nonvolatile storage medium (such as optical disk, flash storage device, mobile hard disk, etc.), including a number of instructions for making a computer device (such as personal computers, servers, network equipment, etc.).

At one level a software element is implemented as a set of commands prepared by the programmer/developer. However, the module software that can be executed by the computer hardware is executable code committed to memory using “machine codes” selected from the specific machine language instruction set, or “native instructions,” designed into the hardware processor. The machine language instruction set, or native instruction set, is known to, and essentially built into, the hardware processor(s). This is the “language” by which the system and application software communicates with the hardware processors. Each native instruction is a discrete code that is recognized by the processing architecture and that can specify particular registers for arithmetic, addressing, or control functions; particular memory locations or offsets; and particular addressing modes used to interpret operands. More complex operations are built up by combining these simple native instructions, which are executed sequentially, or as otherwise directed by control flow instructions.

The inter-relationship between the executable software instructions and the hardware processor is structural. In other words, the instructions per se are a series of symbols or numeric values. They do not intrinsically convey any information. It is the processor, which by design was preconfigured to interpret the symbols/numeric values, which imparts meaning to the instructions.

The models used herein may be configured to execute on a single machine at a single location, on multiple machines at a single location, or on multiple machines at multiple locations. When multiple machines are employed, the individual machines may be tailored for their particular tasks. For example, operations requiring large blocks of code and/or significant processing capacity may be implemented on large and/or stationary machines.

In addition, certain embodiments relate to tangible and/or non-transitory computer readable media or computer program products that include program instructions and/or data (including data structures) for performing various computer-implemented operations. Examples of computer-readable media include, but are not limited to, semiconductor memory devices, phase-change devices, magnetic media such as disk drives, magnetic tape, optical media such as CDs, magneto-optical media, and hardware devices that are specially configured to store and perform program instructions, such as read-only memory devices (ROM) and random access memory (RAM). The computer readable media may be directly controlled by an end user or the media may be indirectly controlled by the end user. Examples of directly controlled media include the media located at a user facility and/or media that are not shared with other entities. Examples of indirectly controlled media include media that is indirectly accessible to the user via an external network and/or via a service providing shared resources such as the “cloud.” Examples of program instructions include both machine code, such as produced by a compiler, and files containing higher level code that may be executed by the computer using an interpreter.

In various embodiments, the data or information employed in the disclosed methods and apparatus is provided in an electronic format. Such data or information may include design layouts, simulation values, sensor values, and the like. As used herein, data or other information provided in electronic format is available for storage on a machine and transmission between machines. Conventionally, data in electronic format is provided digitally and may be stored as bits and/or bytes in various data structures, lists, databases, etc. The data may be embodied electronically, optically, etc.

In some embodiments, a computational model can be viewed as a form of application software that interfaces with a user and with system software. System software typically interfaces with computer hardware and associated memory. In some embodiments, the system software includes operating system software and/or firmware, as well as any middleware and drivers installed in the system. The system software provides basic non-task-specific functions of the computer. In contrast, the modules and other application software are used to accomplish specific tasks. Each native instruction for a module is stored in a memory device and is represented by a numeric value.

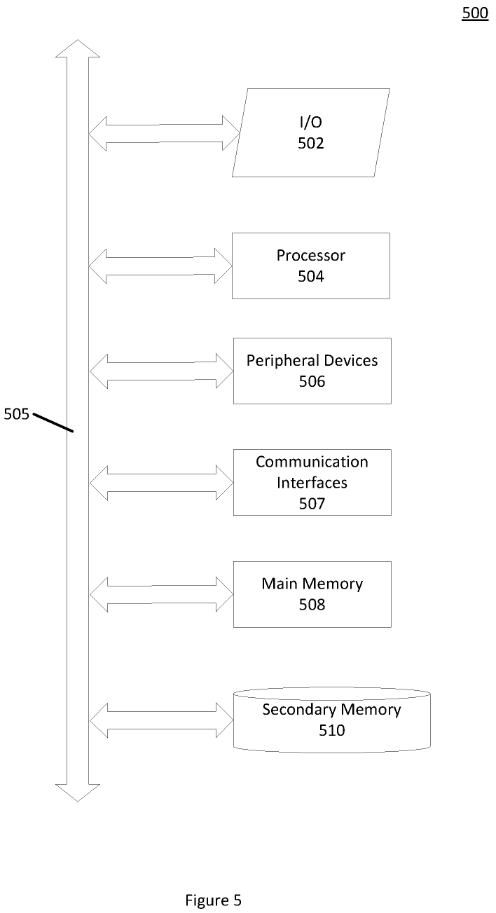

An example computer system 500 is depicted in FIG. 5. As shown, computer system 500 includes an input/output subsystem 502, which may implement an interface for interacting with human users and/or other computer systems depending upon the application. Embodiments of the disclosure may be implemented in program code on system 500 with I/O subsystem 502 used to receive input program statements and/or data from a human user (e.g., via a GUI or keyboard) and to display them back to the user. The I/O subsystem 502 may include, e.g., a keyboard, mouse, graphical user interface, touchscreen, or other interfaces for input, and, e.g., an LED or other flat screen display, or other interfaces for output.

Communication interfaces 507 can include any suitable components or circuitry used for communication using any suitable communication network (e.g., the Internet, an intranet, a wide-area network (WAN), a local-area network (LAN), a wireless network, a virtual private network (VPN), and/or any other suitable type of communication network). For example, communication interfaces 507 can include network interface card circuitry, wireless communication circuitry, etc.

Program code may be stored in non-transitory media such as secondary memory 510 or memory 508 or both. In some embodiments, secondary memory 510 can be persistent storage. One or more processors 504 reads program code from one or more non-transitory media and executes the code to enable the computer system to accomplish the methods performed by the embodiments herein, such as those involved with generating or using a model as described herein. Those skilled in the art will understand that the processor may accept source code, such as statements for executing training and/or modelling operations, and interpret or compile the source code into machine code that is understandable at the hardware gate level of the processor. A bus 505 couples the I/O subsystem 502, the processor 504, peripheral devices 506, communication interfaces 507, memory 508, and secondary memory

CONCLUSION

In the description, numerous specific details were set forth in order to provide a thorough understanding of the presented embodiments. The disclosed embodiments may be practiced without some or all of these specific details. In other instances, well-known process operations were not described in detail to not unnecessarily obscure the disclosed embodiments. While the disclosed embodiments were described in conjunction with the specific embodiments, it will be understood that the specific embodiments are not intended to limit the disclosed embodiments.

Unless otherwise indicated, the method operations and device features disclosed herein involves techniques and apparatus commonly used in metrology, semiconductor device fabrication technology, software design and programming, and statistics, which are within the skill of the art.

Unless defined otherwise herein, all technical and scientific terms used herein have the same meaning as commonly understood by one of ordinary skill in the art. Various scientific dictionaries that include the terms included herein are well known and available to those in the art. Although any methods and materials similar or equivalent to those described herein find use in the practice or testing of the embodiments disclosed herein, some methods and materials are described.

Numeric ranges are inclusive of the numbers defining the range. It is intended that every maximum numerical limitation given throughout this specification includes every lower numerical limitation, as if such lower numerical limitations were expressly written herein. Every minimum numerical limitation given throughout this specification will include every higher numerical limitation, as if such higher numerical limitations were expressly written herein. Every numerical range given throughout this specification will include every narrower numerical range that falls within such broader numerical range, as if such narrower numerical ranges were all expressly written herein.

The headings provided herein are not intended to limit the disclosure.

As used herein, the singular terms “a,” “an,” and “the” include the plural reference unless the context clearly indicates otherwise. The term “or” as used herein, refers to a non-exclusive or, unless otherwise indicated.

Various computational elements including processors, memory, instructions, routines, models, or other components may be described or claimed as “configured to” perform a task or tasks. In such contexts, the phrase “configured to” is used to connote structure by indicating that the component includes structure (e.g., stored instructions, circuitry, etc.) that performs the task or tasks during operation. As such, the unit/circuit/component can be said to be configured to perform the task even when the specified component is not necessarily currently operational (e.g., is not on).

The components used with the “configured to” language may refer to hardware-for example, circuits, memory storing program instructions executable to implement the operation, etc. Additionally, “configured to” can refer to generic structure (e.g., generic circuitry) that is manipulated by software and/or firmware (e.g., an FPGA or a general-purpose processor executing software) to operate in manner that is capable of performing the recited task(s). Additionally, “configured to” can refer to one or more memories or memory elements storing computer executable instructions for performing the recited task(s). Such memory elements may include memory on a computer chip having processing logic. In some contexts, “configured to” may also include adapting a manufacturing process (e.g., a semiconductor fabrication facility) to fabricate devices (e.g., integrated circuits) that are adapted to implement or perform one or more tasks.

1. A digital twin of a process chamber of semiconductor manufacturing equipment, comprising one or more non-transitory machine-readable media comprising logic configured to implement:
a first model of a first location of the process chamber; and
a second model of a second location of the process chamber,
wherein the first model of the first location of the process chamber is coupled to the second model of the second location of the process chamber, and
wherein the first model of the first location of the process chamber and the second model of the second location of the process chamber are each of a model type that is one of: 1) an AI/ML model; 2) an HFS model; or 3) a closed-form solution, and
wherein the first model of the first location of the process chamber and the second model of the second location of the process chamber each represent a class of physical phenomena that is one of: 1) thermal characteristics; 2) plasma characteristics; 3) fluid dynamics; 4) structural characteristics; or 5) chemical reactions.

2. The digital twin of claim 1, wherein the first model of the first location of the process chamber is of a different model type than the second model of the second location of the process chamber.

3. The digital twin of claim 1, wherein the first model of the first location of the process chamber represents a different class of physical phenomena than the second model of the second location of the process chamber.

4. The digital twin of claim 1, wherein the first location is one of: 1) a pedestal of an ESC; 2) a showerhead; 3) a gap between the pedestal and the showerhead; 4) a chamber wall; or 5) a surface of a wafer fabricated by the process chamber.

5. The digital twin of claim 1, wherein the first model of the first location of the process chamber being coupled to the second model of the second location of the process chamber comprises the first model of the first location of the process chamber providing outputs to the second model of the second location of the process chamber for use by the second model of the second location of the process chamber.

6. The digital twin of claim 5, wherein the first model of the first location of the process chamber being coupled to the second model of the second location of the process chamber comprises the first model of the first location of the process chamber receiving outputs from the second model of the second location of the process chamber for use by the first model of the first location of the process chamber.

7. A computer program product for generating digital twins of process chambers, the computer program product comprising a non-transitory computer readable medium on which is provided computer-executable instructions for:
generating a digital twin by:
generating, for a first location of a process chamber, a plurality of High Fidelity Simulation (HFS) values using an HFS model of the first location of the process chamber;
receiving a plurality of sensor measurements corresponding to the first location of the process chamber;
training an Artificial Intelligence/Machine Learning (AI/ML) model of the first location of the process chamber using at least one of the plurality of HFS values and the plurality of sensor measurements; and
coupling the trained AI/ML model of the first location of the process chamber to a model of a second location of the process chamber, wherein the digital twin of the process chamber is comprised of the trained AI/ML model of the first location of the process chamber and the model of the second location of the process chamber.

8. The computer program product of claim 7, wherein the second model of the second location of the process chamber is one of: 1) an AI/ML model; 2) an HFS model; or 3) a closed-form solution.

9. The computer program product of claim 7, wherein the HFS model of the first location of the process chamber and the AI/ML model of the first location of the process chamber both model a same class of physical phenomena.

10. The computer program product of claim 7, wherein the trained AI/ML model of the first location of the process chamber and the model of the second location of the process chamber each model a class of physical phenomena.

11. The computer program product of claim 10, wherein the class of physical phenomena is one of: thermal characteristics, plasma characteristics, fluid dynamics, structural characteristics, or chemical reactions.

12. The computer program product of claim 10, wherein the trained AI/ML model of the first location of the process chamber and the model of the second location of the process chamber model different classes of physical phenomena.

13. The computer program product of claim 7, wherein the HFS model of the first location of the process chamber generates simulation values with a timestep that is shorter than a timestep of the AI/ML model of the first location of the process chamber.

14. The computer program product of claim 7, wherein the first location of the process chamber is one of: 1) a pedestal of an electrostatic chuck (ESC); 2) a showerhead; 3) a gap between the showerhead and the pedestal; 4) a chamber wall; or 5) a surface of a wafer fabricated by the process chamber.

15. The computer program product of claim 7, wherein coupling the trained AI/ML model of the first location of the process chamber to the model of the second location of the process chamber comprises providing a plurality of outputs of the trained AI/ML model of the first location of the process chamber to the model of the second location of the process chamber.

16. The computer program product of claim 15, wherein providing the plurality of outputs of the trained AI/ML model of the first location of the process chamber to the model of the second location of the process chamber comprises:
waiting until the plurality of outputs of the trained AI/ML model of the first location of the process chamber have been received; and
transmitting the plurality of outputs to the model of the second location of the process chamber.

17. The computer program product of claim 7, wherein coupling the trained AI/ML model of the first location of the process chamber to the model of the second location of the process chamber comprises providing a plurality of outputs of the model of the second location of the process chamber to the trained AI/ML model of the first location of the process chamber.

18. The computer program product of claim 7, further comprising computer-executable instructions for validating a performance of the trained AI/ML model of the first location of the process chamber after inclusion of the trained AI/ML model of the first location of the process chamber in the digital twin.

19. The computer program product of claim 18, wherein validating the performance of the trained AI/ML model comprises:
generating simulated data using the digital twin that includes the trained AI/ML model of the first location of the process chamber and the model of the second location of the process chamber; and
comparing the simulated data to experimental data collected using a plurality of sensors associated with a physical process chamber.

20. The computer program product of claim 7, wherein the model of the second location of the process chamber is an HFS model, and further comprising computer-executable instructions for replacing the HFS model of the second location of the process chamber with a trained AI/ML model of the second location in the digital twin.

21. A computer program product for using digital twins of process chambers, the computer program product comprising a non-transitory computer readable medium on which is provided computer-executable instructions for:
identifying a plurality of inputs to a digital twin of a process chamber, wherein the digital twin comprises a first model of a first location of the process chamber and a second model of a second location of the process chamber, and wherein the first model of the first location of the process chamber and the second model of the second location of the process chamber are coupled, and wherein the plurality of inputs represent operating conditions of the process chamber;
providing the plurality of inputs to the digital twin; and
generating predicted wafer characteristics of a simulated wafer using the digital twin.

22. The computer program product of claim 21, wherein the first model of the first location of the process chamber includes specifications of a component of the process chamber, and further comprising computer-executable instructions for validating the specifications of the component based on the predicted wafer characteristics.

23. The computer program product of claim 21, wherein the plurality of inputs include parameters of a recipe implemented by the process chamber, and further comprising computer-executable instructions for validating at least one parameter of the recipe based on the predicted wafer characteristics.

24. The computer program product of claim 21, wherein the predicted wafer characteristics comprise an indication of a defect of the simulated wafer.

25. The computer program product of claim 21, further comprising computer-executable instructions for identifying a recommendation to modify at least one operating condition of the operating conditions based on the predicted wafer characteristics.

26. The computer program product of claim 25, wherein the recommendation is identified in response to determining that the predicted wafer characteristics indicate a defect of the simulated wafer.

27. The computer program product of claim 25, wherein the recommendation is identified in response to determining that at least one of the first model and the second model has generated values that indicate anomalous operating conditions of the process chamber.
